(19) United States
(12) Patent Application Publication
(10) Pub. No.: US 2023/0203229 A1
(43) Pub. Date: Jun. 29, 2023

(54) COMPOSITION, UNDERLAYER FILM, AND DIRECTED SELF-ASSEMBLY LITHOGRAPHY PROCESS

(71) Applicant: JSR CORPORATION, Tokyo (JP)

(72) Inventors: Miki TAMADA, Tokyo (JP); Ryo KUMEGAWA, Tokyo (JP); Motohiro SHIRATANI, Tokyo (JP); Hiroyuki KOMATSU, Tokyo (JP); Ken MARUYAMA, Tokyo (JP); Sosuke OSAWA, Tokyo (JP)

(73) Assignee: JSR CORPORATION, Tokyo (JP)

(21) Appl. No.: 18/108,108

(22) Filed: Feb. 10, 2023

Related U.S. Application Data
(63) Continuation-in-part of application No. PCT/JP2021/029616, filed on Aug. 11, 2021.

(30) Foreign Application Priority Data
Aug. 17, 2020 (JP) 2020-137630

(51) Int. Cl. C08F 297/02; G03F 7/00; G03F 7/075

(52) U.S. Cl. CPC C08F 297/026; G03F 7/0035; G03F 7/0757; C08F 2810/40

(57) ABSTRACT

A composition includes a polymer (1) having a partial structure represented by formula (1), and a solvent. X is a hydrogen atom, a halogen atom, a hydroxyl group, an alkyl group having 1 to 5 carbon atoms, a hydroxyalkyl group having 1 to 5 carbon atoms, or a halogenated alkyl group having 1 to 5 carbon atoms. Y is a monovalent organic group having 1 to 12 carbon atoms and containing a hetero atom or a monovalent inorganic acid group. Z is a linking group represented by —O—, —S—, or —NR—, where R is an organic group having 1 to 20 carbon atoms. R¹ and R² are each independently a hydrogen atom, a halogen atom, or an organic group having 1 to 20 carbon atoms, or the like.

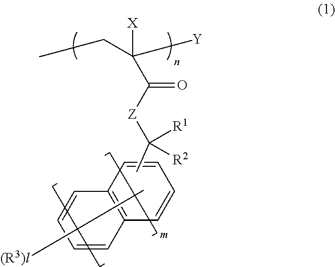

### CROSS-REFERENCE TO RELATED APPLICATIONS

The present application is a continuation-in-part application of International Patent Application No. PCT/JP2021/029616, filed Aug. 11, 2021, which claims priority to Japanese Patent Application No. 2020-137630, filed Aug. 17, 2020. The contents of these applications are incorporated herein by reference in their entirety.

### BACKGROUND OF THE INVENTION

### Field of the Invention

The present invention relates to a composition, an underlayer film of a directed self-assembled film, and a directed self-assembly lithography process.

### Description of the Related Art

Miniaturization of structures of various types of electronic devices such as semiconductor devices and liquid crystal devices has been accompanied by demands for miniaturization of patterns in lithography processes. Today, although fine patterns having a line width of about 90 nm can be formed using, for example, an ArF excimer laser, finer pattern formation is required.

To meet such demands described above, a lithography process which utilizes a phase separation structure by so-called directed self-assembly that spontaneously forms an ordered pattern has been proposed. As such a directed self-assembly lithography process, a method of forming an ultrafine pattern by directed self-assembly using a block copolymer obtained by copolymerizing monomers differing in properties from each other is known (see JP-A-2008-149447, JP-A-2002-519728, and JP-A-2003-218383). When this method is used, annealing of a film containing the block copolymer results in a tendency of clustering of polymer structures having the same property, and thus a pattern can be formed in a self-aligning manner. In addition, a method of forming a fine pattern by directed self-assembling a composition containing a plurality of polymers differing in properties from each other is also known (see US 2009/0214823 A1 and JP-A-2010-058403).

It is known that in such a directed self-assembly lithography process, phase separation by the above-described directed self-assembly is effectively caused by forming a film containing such a component as a polymer to be self-assembled on a specific underlayer film. Various studies have been made on that underlayer film, and it is known that various phase separation structures can be formed by appropriately controlling the surface free energy of an underlayer film when a block copolymer is directed self-assembled (see JP-A-2008-36491 and JP-A-2012-174984). As a polymer to constitute such an underlayer film, for example, a random copolymer composed of two types of monomers having different compositions such as styrene and methyl methacrylate has been proposed.

### SUMMARY OF THE INVENTION

According to an aspect of the present invention, a composition includes a polymer (1) having a partial structure represented by formula (1), and a solvent.

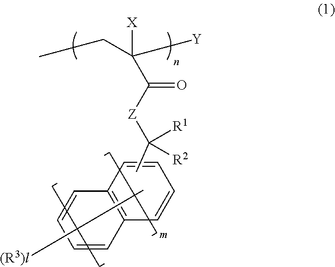

In the formula (1), X is a hydrogen atom, a halogen atom, a hydroxyl group, an alkyl group having 1 to 5 carbon atoms, a hydroxyalkyl group having 1 to 5 carbon atoms, or a halogenated alkyl group having 1 to 5 carbon atoms; n is an integer of 10 to 500; m is an integer of 0 to 3; l is an integer satisfying l=2 m+5; Y is a monovalent organic group having 1 to 12 carbon atoms and containing a hetero atom or a monovalent inorganic acid group; Z is a linking group represented by —O—, —S—, or —NR—, where R is an organic group having 1 to 20 carbon atoms; R¹ and R² are each independently a hydrogen atom, a halogen atom, or an organic group having 1 to 20 carbon atoms, or R¹ and R² taken together represent a divalent cyclic group having 3 to 8 ring atoms together with the carbon atom to which R¹ and R² are bonded; and R³ is a hydrogen atom, a halogen atom or an organic group having 1 to 20 carbon atoms, provided that when there is a plurality of R³s, each R³ is the same or different.

According to another aspect of the present invention, an underlayer film of a directed self-assembled film is formed from the above-described composition.

According to a further aspect of the present invention, a directed self-assembly lithography process includes applying the composition according to claim 1 on one surface of a substrate to form an underlayer film. A composition for directed self-assembled film formation is applied to a surface of the underlayer film, the surface being opposite to a substrate side, to form a directed self-assembled film. The directed self-assembled film is phase-separated to form a plurality of phases in the directed self-assembled film. At least part of the plurality of phases of the directed self-assembled film is removed to form a pattern.

### BRIEF DESCRIPTION OF THE DRAWINGS

FIG. 1 is a schematic cross-sectional view illustrating an embodiment example of a state after an underlayer film is formed in the directed self-assembly lithography process of the present disclosure;

FIG. 2 is a schematic cross-sectional view illustrating an embodiment example of a state after a pre-pattern is formed on an underlayer film in the directed self-assembly lithography process of the present disclosure;

FIG. 3 is a schematic cross-sectional view illustrating an embodiment example of a state after a composition for directed self-assembled film formation is applied to regions on an underlayer film compartmentalized by the pre-pattern in the directed self-assembly lithography process of the present disclosure;

FIG. 4 is a schematic cross-sectional view illustrating an embodiment example of a state after a directed self-assembled film is formed in regions on an underlayer film situated between pre-patterns in the directed self-assembly lithography process of the present disclosure;

FIG. 5 is a schematic cross-sectional view illustrating an embodiment example of a state after a part of a phase of a directed self-assembled film and a pre-pattern are removed in the directed self-assembly lithography process of the present disclosure;

FIG. 6 is a scanning electron micrograph of a fingerprint pattern made in Example 2 of the present disclosure; and

FIG. 7 is a scanning electron micrograph of a fingerprint pattern made in Comparative Example 3 of the present disclosure.

### DESCRIPTION OF THE EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4 7.2 as does the following list of values: 1, 4, 6, 10.

The embodiment of the present invention relates to:

a composition for underlayer film formation of a directed self-assembled film in a directed self-assembly lithography process,

the composition containing a polymer (1) having a partial structure represented by the following formula (1) (hereinafter, also referred to as “partial structure (1)”) and a solvent,

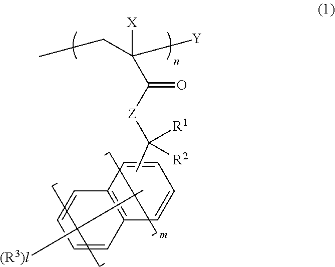

in the formula (1),

X is a hydrogen atom, a halogen atom, a hydroxyl group, an alkyl group having 1 to 5 carbon atoms, a hydroxyalkyl group having 1 to 5 carbon atoms, or a halogenated alkyl group having 1 to 5 carbon atoms;

n is an integer of 10 to 500;

m is an integer of 0 to 3;

l is an integer satisfying l=2 m+5;

Y is a monovalent organic group having 1 to 12 carbon atoms and containing a hetero atom or a monovalent inorganic acid group;

Z is a linking group represented by —O—, —S—, or —NR—, and R is an organic group having 1 to 20 carbon atoms;

R¹ and R² are each independently a hydrogen atom, a halogen atom, or an organic group having 1 to 20 carbon atoms, or R¹ and R² are combined with each other and represent a divalent cyclic group having 3 to 8 ring atoms together with the carbon atoms to which R¹ and R² are bonded; and

R³ is a hydrogen atom, halogen atom or an organic group having 1 to 20 carbon atoms, provided that when there is a plurality of R³s, they may be the same or different.

In the present disclosure, examples of the organic group include a monovalent hydrocarbon group, a group containing a divalent hetero atom-containing group between two adjacent carbon atoms of the hydrocarbon group, and a group resulting from the hydrocarbon group or the group containing a divalent hetero atom-containing group by substituting part or all of the hydrogen atoms included therein with a monovalent hetero atom-containing group.

In the present disclosure, the “hydrocarbon group” includes a chain hydrocarbon group, an alicyclic hydrocarbon group, and an aromatic hydrocarbon group. The “hydrocarbon group” includes both a saturated hydrocarbon group and an unsaturated hydrocarbon group. The “chain hydrocarbon group” refers to a hydrocarbon group that does not include any cyclic structure and is composed only of a chain structure, and includes both a linear hydrocarbon group and a branched hydrocarbon group. The “alicyclic hydrocarbon group” refers to a hydrocarbon group that includes only an alicyclic structure as a ring structure and does not include any aromatic ring structure and includes both a monocyclic alicyclic hydrocarbon group and a polycyclic alicyclic hydrocarbon group. However, it is not necessary for the alicyclic hydrocarbon group to be composed only of an alicyclic structure, and the alicyclic hydrocarbon group may include a chain structure in a part thereof. The “aromatic hydrocarbon group” refers to a hydrocarbon group that includes an aromatic ring structure as a ring structure. However, it is not necessary for the aromatic hydrocarbon group to be composed only of an aromatic ring structure, and the aromatic hydrocarbon group may include a chain structure or an alicyclic structure in a part thereof.

Since the composition for underlayer film formation of the present disclosure contains the polymer (1), it is possible to form an underlayer film which is superior in alignment orientation and forms a phase separation structure with few defects. Conventional underlayer film-forming materials have been prepared using random copolymers of two types of monomers to be used for block copolymers of directed self-assembled materials, such as styrene and methyl methacrylate, so that underlayer films having appropriate affinity for both blocks. However, these are synthesized by radical polymerization and have a wide molecular weight distribution. In contrast, it is presumed that the composition for underlayer film formation of the present disclosure can form an underlayer film having uniform surface free energy owing to the use of a polymer (1) in which most of the polymer structure thereof is occupied by a partial structure (1) having a surface free energy that positions between those of homopolymers of each of two monomers to be used for a block copolymer, for example, polystyrene and polymethyl methacrylate, and as a result, defect performance and the like are improved. The scope of the right of the present invention is not necessarily limited by this presumption of the mechanism of action.

On the other hand, the present disclosure relates to an underlayer film of a directed self-assembled film in a directed self-assembly lithography process which is formed of the composition for underlayer film formation.

Since the underlayer film of the present disclosure is formed of the composition for underlayer film formation containing the polymer (1), it is possible to form a phase separation structure by directed self-assembly and being superior in alignment orientation.

On the other hand, the present disclosure relates to

a directed self-assembly lithography process containing:

a step (1) of forming an underlayer film on one surface of a substrate using the composition for underlayer film formation of the present disclosure;

a step (2) of applying a composition for directed self-assembled film formation to a surface of the underlayer film on a side opposite the substrate;

a step (3) of phase-separating the coating film formed in the application step; and

a step (4) of removing at least part of the phases of the directed self-assembled film formed in the phase separation step.

Since the directed self-assembly lithography process of the present disclosure includes a step using the composition for underlayer film formation of the present disclosure, it is possible to utilize the process for the formation of a good pattern superior in defect performance or the like by using the phase separation structure by directed self-assembly and being superior in alignment orientation.

Hereinbelow, embodiments of the present invention will specifically be described, but the present invention is not limited to these embodiments.

### <Composition for Underlayer Film Formation>

The composition for underlayer film formation of the present disclosure is a composition for forming an underlayer film of a directed self-assembled film in a directed self-assembly lithography process, and

contains a polymer (1) having a partial structure represented by the above formula (1) and a solvent.

The composition for underlayer film formation may further contain other optional components as long as the action and effect of the present invention are not impaired.

### (Polymer (1))

In the present disclosure, the polymer (1) has a partial structure represented by the formula (1).

As to the partial structure, it is usually preferable to use a single type of partial structure, but a plurality of types of partial structure may be used in combination.

The composition for underlayer film formation in the present disclosure is superior in alignment orientation of a phase separation structure by directed self-assembly in a directed self-assembly lithography process. In addition, the polymer (1) that constitutes the composition for underlayer film formation of the present disclosure is mainly composed of a single structure (structural unit (1)), so that a precision polymerization system which leads to a reduced composition distribution, such as living anion polymerization, can be applied. Therefore, it is presumed that an underlayer film having more uniform surface free energy can be formed and defect performance and the like are improved.

In the formula (1), X is a hydrogen atom, a halogen atom, a hydroxyl group, an alkyl group having 1 to 5 carbon atoms, a hydroxyalkyl group having 1 to 5 carbon atoms, or a halogenated alkyl group having 1 to 5 carbon atoms. More specifically, examples of X include halogen atoms such as fluorine atom, a chlorine atom, a bromine atom, and an iodine atom; alkyl groups such as a methyl group, an ethyl group, a n-propyl group, an i-propyl group, a n-butyl group, a sec-butyl group, an i-butyl group, a t-butyl group, a n-pentyl group, and an i-pentyl group; hydroxyalkyl groups such as a hydroxymethyl group, a 1-hydroxyethyl group, and a 2-hydroxyethyl group; and halogenated alkyl groups such as a fluoromethyl group, a trifluoromethyl group, a chloromethyl group, a 1-fluoroethyl group, a 2-fluoroethyl group, a pentafluoroethyl group, a 1-chloroethyl group, and a 2-chloroethyl group.

In the formula (1), n is an integer of 10 to 500. n is preferably 20 or more, and more preferably 30 or more. In addition, n is preferably 400 or less, and more preferably 300 or less. When the value of n falls within the above range, the alignment orientation of the phase separation structure by directed self-assembly using the underlayer film can be further improved.

In the formula (1), m is an integer of 0 to 3. m is preferably 0 or 1.

In the formula (1), 1 is an integer satisfying l=2 m+5. l is preferably 0 to 2.

In the formula (1), Y is a monovalent organic group having 1 to 12 carbon atoms and containing a hetero atom or a monovalent inorganic acid group.

Examples of the monovalent organic group having 1 to 12 carbon atoms and containing a hetero atom include a group containing a divalent heteroatom-containing group between two adjacent carbon atoms of a monovalent hydrocarbon group, and a group resulting from the hydrocarbon group or the group containing a divalent hetero atom-containing group by substituting part or all of the hydrogen atoms included therein with a monovalent hetero atom-containing group.

Examples of the monovalent chain hydrocarbon group having 1 to 12 carbon atoms as the hydrocarbon group include alkyl groups such as a methyl group, an ethyl group, a n-propyl group, and an i-propyl group; alkenyl groups such as an ethenyl group, a propenyl group, and a butenyl group; and alkynyl groups such as an ethynyl group, a propynyl group, and a butynyl group.

Examples of the monovalent alicyclic hydrocarbon group having 3 to 12 carbon atoms include monocyclic alicyclic saturated hydrocarbon groups such as a cyclopentyl group and a cyclohexyl group; monocyclic alicyclic unsaturated hydrocarbon groups such as a cyclopentenyl group and a cyclohexenyl group; polycyclic alicyclic saturated hydrocarbon groups such as a norbornyl group and an adamantyl group; and polycyclic alicyclic unsaturated hydrocarbon groups such as a norbornenyl group.

In addition, examples of the monovalent aromatic hydrocarbon group having 6 to 12 carbon atoms include aryl groups such as a phenyl group, a tolyl group, a xylyl group, a naphthyl group, and an anthryl group; and aralkyl groups such as a benzyl group, a phenethyl group, a naphthylmethyl group, and an anthrylmethyl group.

Examples of the hetero atom constituting the monovalent and divalent hetero atom-containing groups include an oxygen atom, a nitrogen atom, a sulfur atom, a phosphorus atom, a silicon atom, and a halogen atom. Examples of the halogen atom include a fluorine atom, a chlorine atom, a bromine atom, and an iodine atom.

Examples of the divalent hetero atom-containing group include —O—, —CO—, —S—, —CS—, —NR′—, and groups in which two or more of the foregoing are combined. R′ is a hydrogen atom or a monovalent hydrocarbon group.

Examples of the monovalent heteroatom-containing group include halogen atoms such as a fluorine atom, a chlorine atom, a bromine atom, and an iodine atom, a hydroxyl group, a carboxyl group, a cyano group, an amino group, and a sulfanyl group.

The monovalent inorganic acid group may be a substituted group in which part or entire of the inorganic acid is esterified. Examples thereof include a phosphoric acid group, a phosphate ester group, a sulfonic acid group, a sulfonate ester group, and a sulfinate ester group.

One end group Y of the polymer (1) is preferably, for example, a cyano group, an amino group, a hydroxyl group, a phosphoric acid group, a phosphate ester group, a sulfonic acid group, a sulfonate ester group, a sulfinate ester group, or a group having a halogen atom. The other end group of the polymer (1) is the same as or different from Y.

In the formula (1), Z is a linking group represented by —O—, —S—, or —NR—, and R is an organic group having 1 to 20 carbon atoms.

R is an organic group having 1 to 20 carbon atoms, and the definition of the organic group is the same as described above.

Examples of the monovalent chain hydrocarbon group having 1 to 20 carbon atoms include alkyl groups such as a methyl group, an ethyl group, a n-propyl group, and an i-propyl group, alkenyl groups such as an ethenyl group, a propenyl group, and a butenyl group, and alkynyl groups such as an ethynyl group, a propynyl group, and a butynyl group.

Examples of the monovalent alicyclic hydrocarbon group having 3 to 20 carbon atoms include monocyclic alicyclic saturated hydrocarbon groups such as a cyclopentyl group and a cyclohexyl group, monocyclic alicyclic unsaturated hydrocarbon groups such as a cyclopentenyl group and a cyclohexenyl group, polycyclic alicyclic saturated hydrocarbon groups such as a norbornyl group, an adamantyl group and a tricyclodecyl group, and polycyclic alicyclic unsaturated hydrocarbon groups such as a norbornenyl group and a tricyclodecenyl group.

Examples of the monovalent aromatic hydrocarbon group having 6 to 20 carbon atoms include aryl groups such as a phenyl group, a tolyl group, a xylyl group, a naphthyl group, and an anthryl group, and aralkyl groups such as a benzyl group, a phenethyl group, a naphthylmethyl group, and an anthrylmethyl group.

Examples of the hetero atom constituting the monovalent and divalent hetero atom-containing groups include an oxygen atom, a nitrogen atom, a sulfur atom, a phosphorus atom, a silicon atom, and a halogen atom. Examples of the halogen atom include a fluorine atom, a chlorine atom, a bromine atom, and an iodine atom.

Examples of the divalent hetero atom-containing group include —O—, —CO—, —S—, —CS—, —NR′—, and groups in which two or more of the foregoing are combined. R′ is a hydrogen atom or a monovalent hydrocarbon group.

Examples of the monovalent heteroatom-containing group include halogen atoms such as a fluorine atom, a chlorine atom, a bromine atom, and an iodine atom, a hydroxyl group, a carboxyl group, a cyano group, an amino group, and a sulfanyl group.

The Z is preferably, for example, —O—, —N(CH₃)—, or —N(CH₂C₆H₅)—, or the like.

In the formula (1), R¹ and R² are each independently a hydrogen atom, a halogen atom, or an organic group having 1 to 20 carbon atoms, or R¹ and R² are combined with each other and represent a divalent cyclic group having 3 to 8 ring atoms together with the carbon atoms to which R¹ and R² are bonded. Examples of the halogen atom and the organic group are the same as those described above.

The divalent cyclic group having 3 to 8 ring atoms is a group having a cyclic structure configured by R¹ and R² combined with each other together with the carbon atoms to which R¹ and R² are bonded. The cyclic group is not particularly limited as long as it is a group obtained by removing two hydrogen atoms from a single carbon atom constituting the carbocycle of the monocyclic or polycyclic alicyclic hydrocarbon having the above-mentioned number of carbon atoms. The group may be either a monocyclic hydrocarbon group or a polycyclic hydrocarbon group, and the polycyclic hydrocarbon group may be either a bridged alicyclic hydrocarbon group or a fused alicyclic hydrocarbon group, and may be either a saturated hydrocarbon group or an unsaturated hydrocarbon group. It is to be noted that the fused alicyclic hydrocarbon group refers to a polycyclic alicyclic hydrocarbon group in which two or more alicyclic rings share a side (a bond between two adjacent carbon atoms).

Among the monocyclic alicyclic hydrocarbon groups, as the saturated hydrocarbon group, a cyclopentanediyl group, a cyclohexanediyl group, a cycloheptanediyl group, and a cyclooctanediyl group are preferable, and as the unsaturated hydrocarbon group, a cyclopentenediyl group, a cyclohexenediyl group, a cycloheptenediyl group, and a cyclooctenediyl group are preferable. As the polycyclic alicyclic hydrocarbon group, bridged alicyclic saturated hydrocarbon groups are preferable, and for example, a bicyclo[2.2.1]heptane-2,2-diyl group (norbornane-2,2-diyl group) and a bicyclo[2.2.2]octane-2,2-diyl group are preferable.

R¹ and R² are preferably, for example, a hydrogen atom, a methyl group, or the like.

In the formula (1), R³ is a hydrogen atom, a halogen atom or an organic group having 1 to 20 carbon atoms. When there is a plurality of R³s, they may be the same or different. Examples of the halogen atom and the organic group are the same as those described above.

The polymer (1) is preferably, for example, any one of polymers (2) to (4) having partial structures represented by the following formulas (2) to (4).

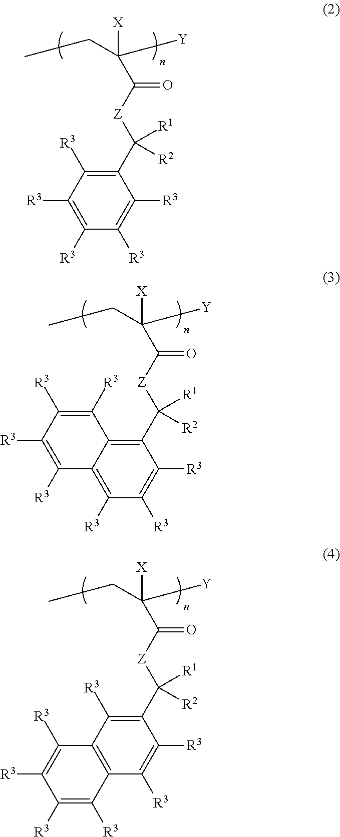

(In the formulas (2) to (4), X, Y, Z, R¹, R², and R³ have the same definitions as those of the formula (1).)

The proportion of the partial structure contained in the polymer (1) is particularly preferably 100 mol % with exclusion of a structure derived from an initiator or the like, but the polymer (1) may have other partial structures. The proportion of the partial structure contained is preferably 30 mol % or more, more preferably 50 mol % or more, even more preferably 60 mol % or more, and particularly preferably 70 mol % or more. When the proportion falls within the above range, the alignment orientation of the phase separation structure by directed self-assembly using the underlayer film can be further improved.

The polymer (1) may include other structures than the partial structure represented by the formula (1) as long as the action and effect of the present invention are not impaired. Examples of the other structure include a repeating unit derived from substituted or unsubstituted styrene, a repeating unit derived from a (meth)acrylate ester, a repeating unit containing an Si—O bond in the main chain, a repeating unit derived from a hydroxycarboxylic acid, a repeating unit derived from an alkylene carbonate, and a repeating unit derived from an alkylene glycol, and as described above, usually, a higher proportion of the above-mentioned partial structure contained in the polymer (1) is preferable in terms of the alignment orientation of the phase separation structure by directed self-assembly.

Examples of the polymer (1) include the following.

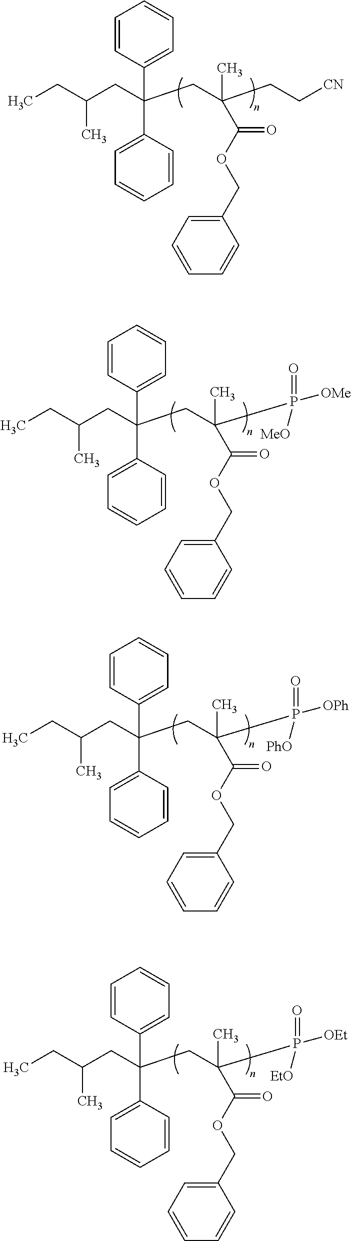

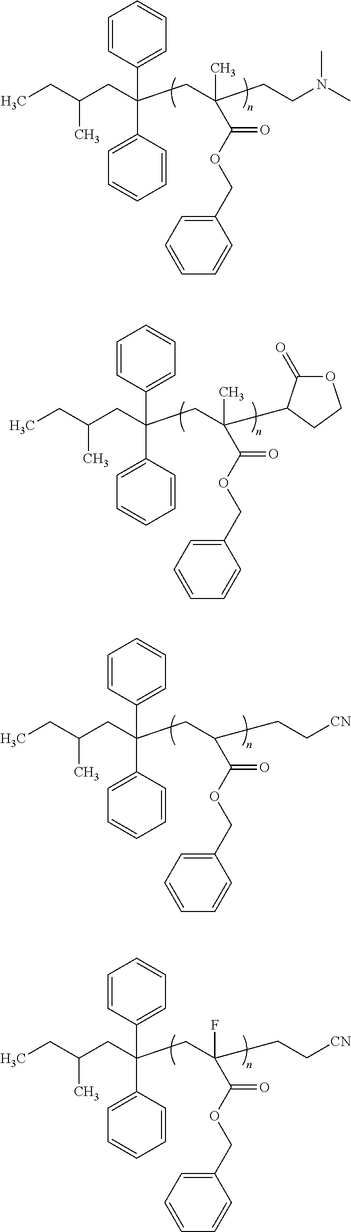

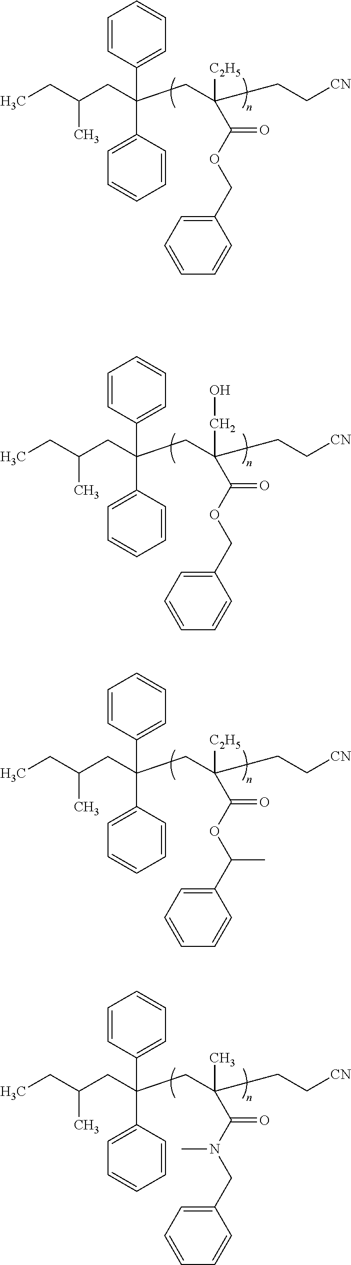

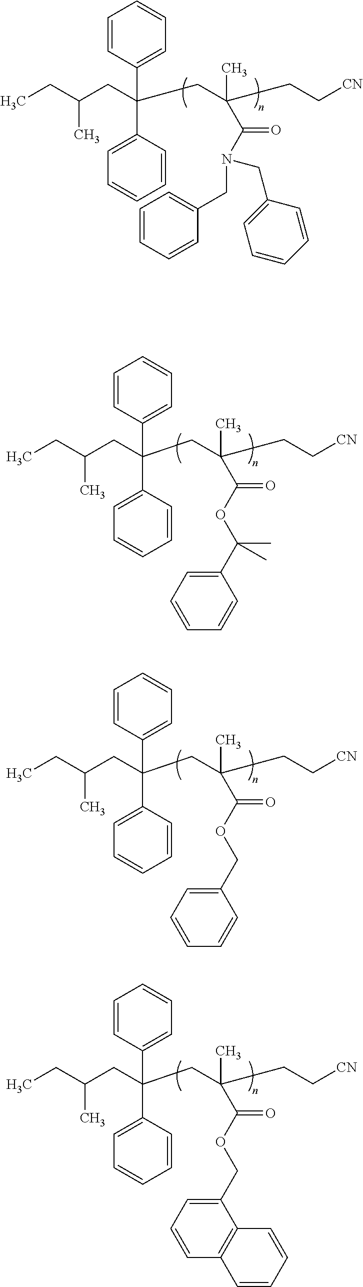

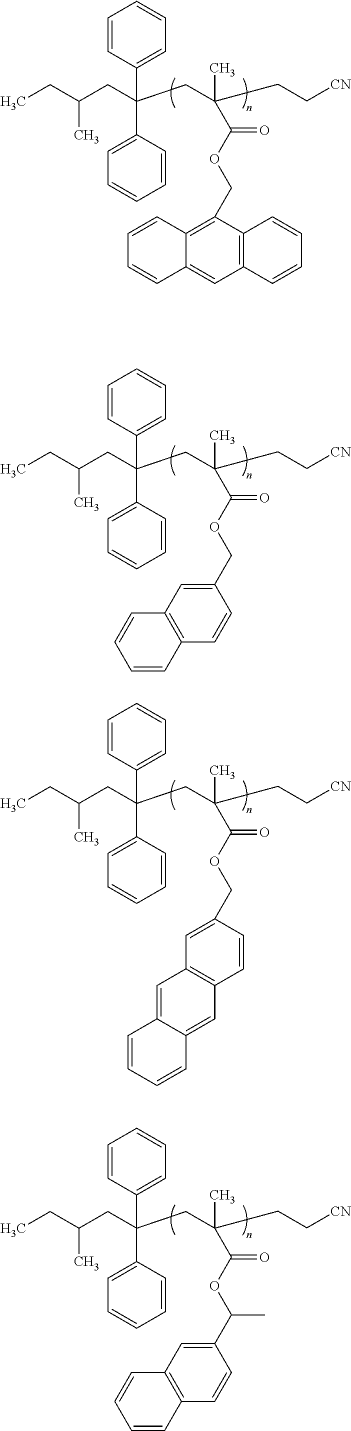

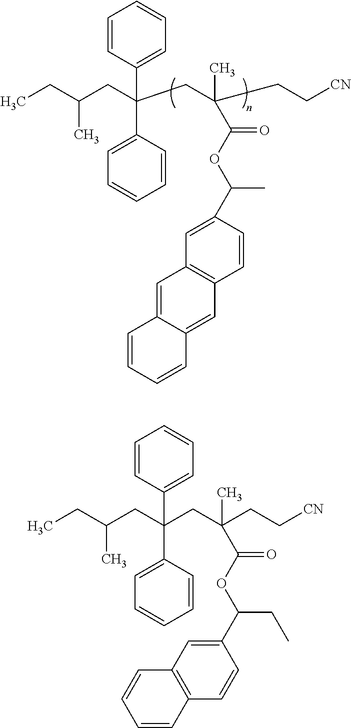

The polymer (1) can be synthesized, for example, by anionic polymerization or controlled radical polymerization of monomers that will afford each structural unit using a polymerization initiator.

The polymer (1) is preferably a polymer obtained by anionic polymerization. The polymer (1) can be synthesized not only by radical polymerization but also by anionic polymerization, and this makes it possible to afford a polymer having a narrow molecular weight distribution. As a result, the composition for underlayer film formation of the present disclosure containing the polymer (1) can more suitably form an underlayer film having uniform surface free energy.

The molecular weight of the polymer (1) is not particularly limited, and the weight average molecular weight (Mw) as determined by Gel Permeation Chromatography (GPC) relative to standard polystyrene is preferably 1,000 to 50,000, more preferably 2,000 to 30,000, even more preferably 3,000 to 15,000, and particularly preferably 4,000 to 12,000. When the Mw of the polymer (1) falls within the above range, the film formability and heat resistance of the resulting underlayer film can be further improved.

The molecular weight distribution (Mn/Mw) of the polymer (1) is preferably 1.10 or less, preferably 1 to 1.10, more preferably 1 to 1.09, and even more preferably 1 to 1.08. When the Mn and the Mw/Mn of the polymer (1) fall within the above ranges, the alignment orientation of the phase separation structure by directed self-assembly using the underlayer film can be further improved.

The Mw and the Mn of a resin in the present description are values measured using gel permeation chromatography (GPC) under the following conditions.

GPC column: two G2000HXL, one G3000HXL, one G4000HXL (all manufactured by Tosoh Corporation)

Column temperature: 40° C.

Elution solvent: tetrahydrofuran

Flow rate: 1.0 mL/min

Sample concentration: 1.0% by mass

Amount of sample injected: 100 μL

Detector: differential refractometer

Standard substance: monodisperse polystyrene

### (Solvent)

The composition for underlayer film formation contains a solvent. The solvent is not particularly limited as long as it is a solvent capable of dissolving or dispersing at least the polymer (1) and the like.

Examples of the solvent include an alcohol-based solvent, an ether-based solvent, a ketone-based solvent, an amide-based solvent, an ester-based solvent, and a hydrocarbon-based solvent.

Examples of the alcohol-based solvent include aliphatic monoalcohol-based solvents having 1 to 18 carbon atoms, such as 4-methyl-2-pentanol and n-hexanol;

alicyclic monoalcohol-based solvents having 3 to 18 carbon atoms, such as cyclohexanol;

polyhydric alcohol-based solvents having 2 to 18 carbon atoms, such as 1,2-propylene glycol; and

partially-etherified polyhydric alcohol-based solvents having 3 to 19 carbon atoms, such as propylene glycol monomethyl ether.

Examples of the ether-based solvent include dialkyl ether-based solvents, such as diethyl ether, dipropyl ether, and dibutyl ether dipentyl ether, diisoamyl ether, dihexyl ether, and diheptyl ether;

cyclic ether-based solvents, such as tetrahydrofuran and tetrahydropyran; and

aromatic ring-containing ether-based solvents, such as diphenyl ether and anisole.

Examples of the ketone-based solvent include chain ketone-based solvents, such as acetone, methyl ethyl ketone, methyl-n-propyl ketone, methyl-n-butyl ketone, diethyl ketone, methyl-iso-butyl ketone, 2-heptanone, ethyl-n-butyl ketone, methyl-n-hexyl ketone, di-iso-butyl ketone, and trimethylnonanone;

cyclic ketone-based solvents, such as cyclopentanone, cyclohexanone, cycloheptanone, cyclooctanone, and methylcyclohexanone; and

2,4-pentanedione, acetonylacetone, and acetophenone.

Examples of the amide-based solvent include cyclic amide-based solvents, such as N,N′-dimethylimidazolidinone and N-methylpyrrolidone; and

chain amide-based solvents, such as N-methylformamide, N,N-dimethylformamide, N,N-diethylformamide, acetamide, N-methylacetamide, N,N-dimethylacetamide, and N-methylpropionamide.

Examples of the ester-based solvent include acetate ester-based solvents, such as n-butyl acetate;

monocarboxylate ester-based solvents, such as lactate ester-based solvents, such as ethyl lactate and butyl lactate;

polyhydric alcohol carboxylate-based solvents, such as propylene glycol acetate;

polyhydric alcohol partial ether carboxylate-based solvent, such as propylene glycol monomethyl ether acetate;

polyvalent carboxylate diester-based solvents, such as diethyl oxalate; and

carbonate-based solvents, such as dimethyl carbonate, diethyl carbonate, ethylene carbonate, and propylene carbonate.

Examples of the hydrocarbon-based solvent include aliphatic hydrocarbon-based solvents having 5 to 12 carbon atoms, such as n-pentane and n-hexane; and

aromatic hydrocarbon-based solvents having 6 to 16 carbon atoms, such as toluene and xylene.

As the solvent, for example, an ester-based solvent is preferable, a polyhydric alcohol partial ether carboxylate-based solvent and/or a lactate ester-based solvent is more preferable, and propylene glycol monomethyl ether acetate and/or ethyl lactate is even more preferable.

The composition for underlayer film formation may contain one or two or more of the solvents disclosed above.

(Other Optional Components)

The composition for underlayer film formation may contain other optional components in addition to the components described above. Examples of the other optional components include a surfactant and a crosslinking agent. The surfactant is a component capable of improving the coating characteristics of the composition for underlayer film formation. When a crosslinking agent is contained, a crosslinking reaction between the crosslinking agent and the polymer (1) occurs, and the heat resistance of an underlayer film to be formed can be improved. Such other optional components may be used singly or two or more types thereof may be used in combination.

Since the composition for underlayer film formation of the present disclosure has the above characteristics, it can be particularly suitably used for underlayer film formation treatment onto a silicon-containing substrate in a directed self-assembly lithography process.

In addition, since the composition for underlayer film formation of the present disclosure has the above characteristics, it can be particularly suitably used for underlayer film formation treatment onto a metal-containing film in a directed self-assembly lithography process.

### (Method for Preparing Composition for Underlayer Film Formation)

The composition for underlayer film formation of the present disclosure can be prepared, for example, by mixing the polymer (1), a solvent, and optional components as necessary in a prescribed ratio, and preferably filtering the resulting mixture through, for example, a filter having pores as large as about 0.45 μm. The lower limit of the solid concentration of the composition for underlayer film formation is preferably 0.1% by mass, more preferably 0.5% by mass, even more preferably 0.8% by mass, and particularly preferably 1% by mass. The upper limit of the solid concentration is preferably 50% by mass, more preferably 30% by mass, even more preferably 10% by mass, and particularly preferably 5% by mass.

In addition, a known method can be appropriately used in the adjustment of the composition for underlayer film formation.

### <Underlayer Film>

The underlayer film of the present disclosure is an underlayer film of a directed self-assembled film in a directed self-assembly lithography process which is formed of the composition for underlayer film formation.

Since the underlayer film of the present disclosure is formed of the composition for underlayer film formation containing the polymer (1) having a partial structure represented by the formula (1), it is possible to form a phase separation structure by directed self-assembly and being superior in alignment orientation.

For the formation of the underlayer film, a known method can be appropriately used using the composition for underlayer film formation. For example, the method described in the section of the directed self-assembly lithography process and the like can be employed.

### <Directed Self-Assembly Lithography Process>

The directed self-assembly lithography process of the present disclosure includes:

a step (1) of forming an underlayer film on one surface of a substrate using the composition for underlayer film formation;

a step (2) of applying a composition for directed self-assembled film formation to a surface of the underlayer film on a side opposite the substrate;

a step (3) of phase-separating the coating film formed in the application step; and

a step (4) of removing at least part of the phases of the directed self-assembled film formed in the phase separation step.

Since the directed self-assembly lithography process of the present disclosure includes a step using the composition for underlayer film formation containing the polymer (1) having a partial structure represented by the above formula (1), it is possible to utilize the process for the formation of a good pattern superior in defect performance or the like by using the phase separation structure by directed self-assembly and being superior in alignment orientation.

Directed self-assembly refers to a phenomenon in which a tissue or a structure is spontaneously constructed without being caused only by control from an external factor. In the present disclosure, a pattern (miniaturized pattern) can be formed by for example, applying a composition for directed self-assembled film formation onto an underlayer film formed from a specific composition for underlayer film formation, thereby forming a film (directed self-assembled film) having a phase separation structure by directed self-assembly, and then removing part of the phases in the directed self-assembled film.

The directed self-assembly lithography process includes: a step (1) of forming an underlayer film on one surface of a substrate using the above-described composition for underlayer film formation (this step is hereinafter also referred to as “underlayer film formation step”); a step (2) of applying a composition for directed self-assembled film formation to a surface of the underlayer film on a side opposite the substrate (this step is hereinafter also referred to as “application step”); a step (3) of phase-separating the coating film formed in the application step (this step is hereinafter also referred to as “phase separation step”); and a step (4) of removing at least part of the phases of the directed self-assembled film formed in the phase separation step (this step is hereinafter also referred to as “removing step”).

In addition, the directed self-assembly lithography process may include, for example, a step (5) of etching the substrate using a pattern formed in the removing step (the step (4)) (this step is hereinafter also referred to as “etching step”).

In addition, the directed self-assembly lithography process may include, prior to the application step (the step (2)), a step (6) of forming a pre-pattern on a directed self-assembled film-formed surface side of the underlayer film or the substrate (this step is hereinafter also referred to as “pre-pattern formation step”). In this case, in the application step, the composition for directed self-assembled film formation is charged into a recess of the pre-pattern.

Hereinafter, each step will be described with reference to drawings.

### [Underlayer Film Formation Step]

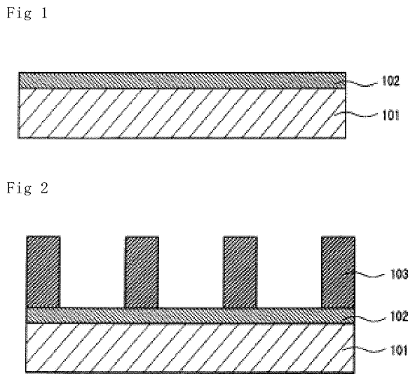

In this step, an underlayer film is formed on one surface of the substrate using the composition for underlayer film formation. As a result, a substrate with an underlayer film in which an underlayer film 102 is formed on the substrate 101 is obtained as illustrated in FIG. 1. The directed self-assembled film is stacked on the underlayer film 102. In the formation of the phase separation structure (microdomain structure) of the directed self-assembled film, it is considered that an interaction between the component constituting the directed self-assembled film and the underlayer film 102 effectively works in addition to an interaction in that component itself, and this makes it possible to control the phase separation structure, and this results in superior alignment orientation of the phase separation structure by directed self-assembly.

As the substrate 101, for example, a conventionally known substrate such as a silicon-containing substrate such as a silicon wafer or a metal-containing film such as a wafer coated with aluminum can be used. The underlayer film 102 can be formed by curing a coating film formed by applying the composition for underlayer film formation onto the substrate 101 by a known method such as a spin coating method by heating and/or exposure.

Examples of the radiation to be used for the exposure include visible light, ultraviolet rays, far ultraviolet rays, X-rays, electron beams, γ-rays, molecular beams, and ion beams.

As the conditions for forming the underlayer film, the lower limit of the heating temperature of the coating film is preferably 100° C., more preferably 120° C., even more preferably 150° C., and particularly preferably 180° C. The upper limit of the heating temperature is preferably 400° C., more preferably 300° C., even more preferably 240° C., and particularly preferably 220° C. The lower limit of the heating time of the coating film is preferably 10 seconds, more preferably 15 seconds, and even more preferably 30 seconds. The upper limit of the heating time is preferably 30 minutes, more preferably 10 minutes, and even more preferably 5 minutes. When the heating temperature and time in forming the underlayer film fall within the above ranges, an underlayer film can be easily and reliably formed. The atmosphere for heating the coating film may be either an air atmosphere or an inert gas atmosphere such as nitrogen gas.

The lower limit of the average thickness of the underlayer film 102 is preferably 5 nm, more preferably 10 nm, even more preferably 15 nm, and particularly preferably 20 nm. The upper limit of the average thickness is preferably 20,000 nm, more preferably 1,000 nm, even more preferably 500 nm, and particularly preferably 100 nm.

The lower limit of the static contact angle with pure water on a surface of the underlayer film 102 is preferably 60°, more preferably 70°, and even more preferably 75°. The upper limit of the static contact angle is preferably 95°, more preferably 90°, and even more preferably 85°. When the static contact angle of the surface of the underlayer film falls within the above range, the alignment orientation of the phase separation structure by directed self-assembly can be further improved.

### [Pre-Pattern Formation Step]

This step may be provided either before or after the underlayer film formation step, but is preferably provided after the underlayer film formation step.

In this step, a pre-pattern is formed on a directed self-assembled film-formed surface side of the underlayer film or the substrate. Preferably, a pre-pattern 103 is formed on the underlayer film 102 using a composition for pre-pattern formation as illustrated in FIG. 2. The pre-pattern 103 is provided for the purpose of controlling phase separation at the time of forming a directed self-assembled film to better form a phase separation structure by directed self-assembly. That is, among the components forming the directed self-assembled film, a component having high affinity with a side surface of the pre-pattern forms a phase along the pre-pattern, and a component having low affinity forms a phase at a position away from the pre-pattern. This makes it possible to form a phase separation structure more clearly by directed self-assembly.

In addition, the phase separation structure to be formed can be finely controlled by the material, length, thickness, shape, and the like of the pre-pattern. It is noted that the shape of the pre-pattern can be appropriately chosen according to a pattern intended to be finally formed, and for example, a line-and-space pattern, a hole pattern, a pillar pattern, or the like can be employed.

As a method for forming the pre-pattern 103, the same method as a known method for forming a resist pattern can be used. As the composition for forming the pre-pattern, a conventional composition for resist film formation can be used.

As a specific method for forming the pre-pattern 103, for example, a chemically amplified resist composition such as “AEX1191JN” (ArF immersion resist) produced by JSR Corporation is applied onto the underlayer film 102 to form a resist film. Next, a desired region of the resist film is irradiated with radiation through a mask with a specific pattern to perform exposure. Examples of the radiation include electromagnetic waves such as ultraviolet rays, far ultraviolet rays, and X-rays, and charged particle beams such as electron beams. Among them, far ultraviolet rays are preferable, and ArF excimer laser light or KrF excimer laser light is more preferable. Subsequently, post exposure baking (PEB) is conducted, and development is performed using a developer such as an alkaline developer, so that a desired pre-pattern 103 can be formed.

A surface of the pre-pattern 103 may be subjected to hydrophobization treatment or hydrophilization treatment. Specific examples of the treatment method include hydrogenation treatment in which the surface is exposed to hydrogen plasma for a certain period of time. Increasing the hydrophobicity or hydrophilicity of a surface of the pre-pattern 103 can promote the directed self-assembly described above.

### [Application Step]

In this step, the composition for directed self-assembled film formation is applied to a surface of the underlayer film on a side opposite the substrate.

Examples of the composition for directed self-assembled film formation include a composition in which a component capable of forming a phase separation structure by directed self-assembly is dissolved in a solvent or the like.

Examples of the component capable of forming a phase separation structure by the directed self-assembly include a block copolymer and a mixture of two or more polymers incompatible with each other. Among them, from the viewpoint of being able to form a clearer phase separation structure, a block copolymer is preferable, a block copolymer composed of a styrene unit and a methacrylate ester unit is more preferable, and a diblock copolymer composed of a styrene unit and a methyl methacrylate unit is even more preferable.

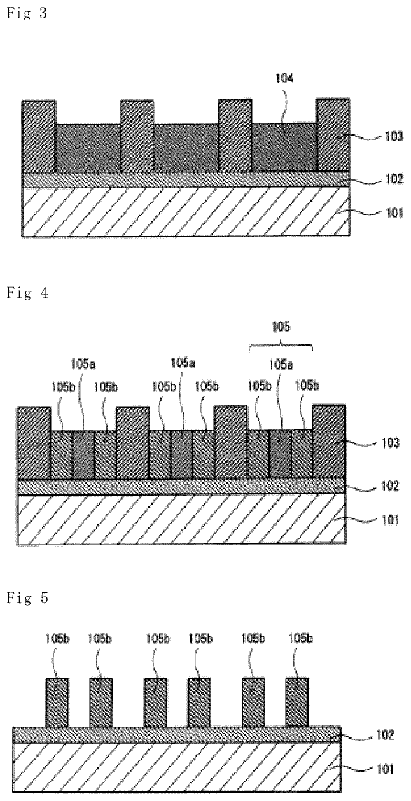

Examples of the method for applying the composition for directed self-assembled film formation include a spin coating method. As illustrated in FIG. 3, the composition for directed self-assembled film formation is applied to between pre-patterns 103 or the like on the underlayer film 102 to form a coating film 104.

[Phase Separation Step]

In this step, the coating film formed in the application step is phase-separated. As a result, a directed self-assembled film 105 as illustrated in FIG. 4 is formed.

In the phase separation of the coating film 104 of the composition for directed self-assembled film formation, annealing or the like can promote so-called directed self-assembly, in which sites having the same properties are accumulated to spontaneously form an ordered pattern. As a result, a phase separation structure is formed on the underlayer film 102 as illustrated in FIG. 4. The phase separation structure is preferably formed along the pre-pattern, and the interface formed by the phase separation is more preferably substantially parallel to a side surface of the pre-pattern.

For example, when the pre-pattern 103 is a line pattern, a phase 105b of a component or the like having higher affinity with the pre-pattern 103 is formed along the pre-pattern 103, whereas a phase 105a of the other component or the like is formed in a portion farthest from a side surface of the pre-pattern, that is, in a central portion of a region divided by the pre-pattern and a lamellar phase separation structure in which lamellar (plate-like) phases are alternately arranged is formed.

When the pre-pattern is a hole pattern, a phase of a component or the like having higher affinity with the pre-pattern is formed along a hole side surface of the pre-pattern, and a phase of the other component or the like is formed at the center portion of the hole.

When the pre-pattern is a pillar pattern, a phase of a component or the like having higher affinity with the pre-pattern is formed along a side surface of the pillar of the pre-pattern, and a phase of the other component or the like is formed in a portion away from each pillar. A desired phase separation structure can be formed by appropriately adjusting the distance between the pillars of the pre-pattern, the structure and blending ratio of the components such as each polymer in the directed self-assembly composition, and the like.

The phase separation structure formed includes a plurality of phases, and the interface formed by these phases is usually substantially vertical, but the interface itself is not required to have strict clarity. A resulting phase separation structure can be precisely controlled and a desired fine pattern can be obtained by the structure and blending ratio of the component of each polymer and the pre-pattern in addition to the underlayer film as described above.

Examples of the annealing method include heating with an oven, a hot plate, or the like. The lower limit of the heating temperature is preferably 80° C., and more preferably 100° C. The upper limit of the heating temperature is preferably 400° C., and more preferably 300° C. The lower limit of the annealing time is preferably 10 seconds, and more preferably 30 seconds. The upper limit of the time is preferably 120 minutes, and more preferably 60 minutes.

The lower limit of the average thickness of the resulting directed self-assembled film 105 is preferably 0.1 nm, and more preferably 0.5 nm. The upper limit of the average thickness is preferably 500 nm, and more preferably 100 nm.

### [Removing Step]

In this step, at least part of the phases of the directed self-assembled film formed in the phase separation step is removed. Thus, a miniaturized pattern is formed.

Part of the phase 105a and/or the pre-pattern 103 can be removed by etching treatment utilizing a difference in etching rate among the phases separated by directed self-assembly. FIG. 5 illustrates a state after removing part of the phase 105a and the pre-pattern 103 in the phase separation structure.

Examples of a method for removing part of the phase 105a or the pre-pattern 103 in the phase separation structure of the directed self-assembled film 105 include such known methods as reactive ion etching (RIE) such as chemical dry etching or chemical wet etching and physical etching such as sputter etching and ion beam etching. Among them, reactive ion etching (RIE) is preferable, and chemical dry etching using CF₄, O₂ gas or the like, and chemical wet etching (wet development) using an organic solvent such as methyl isobutyl ketone (MIBK) or 2-propanol (IPA), or a liquid etching solution such as hydrofluoric acid is more preferable.

### [Etching Step]

In this step, the substrate is etched using a pattern such as a miniaturized pattern formed in the removing step. Thus, a substrate pattern can be formed.

The substrate can be patterned by etching the underlayer film and the substrate using, as a mask, the miniaturized pattern composed of part of the phase 105b of the directed self-assembled film remaining as a result of the removing step. After the patterning to the substrate is completed, the phase used as the mask is removed from the substrate by dissolution treatment or the like, and finally, a substrate pattern (a patterned substrate) can be obtained. Examples of the pattern to be obtained include a line-and-space pattern and a hole pattern.

As a method of the etching, the same methods as the methods of etching disclosed as examples in the section of the removing step can be used. Among them, dry etching is preferable. The gas to be used for dry etching can be appropriately selected according to the material of the substrate. For example, when the substrate is made of a silicon material, a mixed gas of a fluorocarbon gas and SF₄ or the like can be used. When the substrate is a metal film, a mixed gas of BCl₃ and Cl₂ or the like can be used.

In addition, known technique can be appropriately used in the directed self-assembly lithography process.

The pattern obtained by the directed self-assembly lithography process is suitably used for semiconductor elements and the like, and further the semiconductor elements are widely used for LEDs, solar cells, and the like.

### EXAMPLES

Next, the present invention will specifically be described on the basis of examples, but is not limited to these examples. Methods for measuring various physical property values will be described below.

### [Mw and Mn]

The Mw and the Mn of polymers were measured by gel permeation chromatography (GPC) using GPC columns manufactured by Tosoh Corporation (“G2000HXL” x 2, “G3000HXL” x 1, “G4000HXL” x 1) under the following conditions.

Eluant: tetrahydrofuran (manufactured by Wako Pure Chemical Industries, Ltd.)

Flow rate: 1.0 mL/min

Sample concentration: 1.0% by mass

Amount of sample injected: 100 μL

Column temperature: 40° C.

Detector: differential refractometer

Standard substance: monodisperse polystyrene

### <Synthesis of Polymer [A]>

The following monomers were used for the synthesis of the polymers for underlayer film formation.

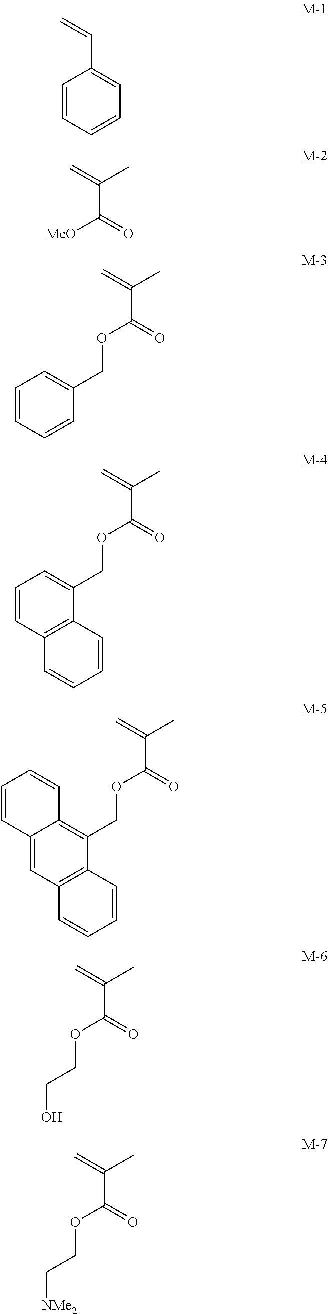

The following end treatment agents were used for the synthesis of the polymers for underlayer film formation.

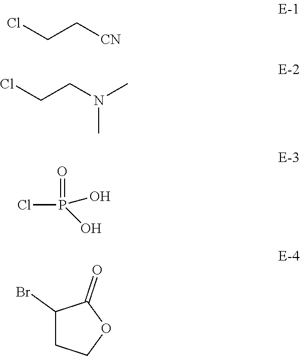

### [Synthesis Example 1] (Synthesis of Polymer (A-1))

A 500 mL flask reaction vessel was dried under reduced pressure, and then 100 g of tetrahydrofuran which had been subjected to dehydration treatment by distillation was charged into the vessel under a nitrogen atmosphere, and cooled to −78° C. Thereafter, 2.0 g of a 1 N sec-butyllithium (sec-BuLi) solution in cyclohexane was charged, and then 1.0 g of 1,1-diphenylethylene which had been subjected to dehydration treatment was charged. After stirring at −78° C. for 10 minutes, 18.1 g of M-3 which had been subjected to dehydration treatment by distillation was added dropwise over 30 minutes. After completion of the dropwise addition, the resulting mixture was subjected to a reaction for 120 minutes, and then E-1 was charged as an end treatment agent and the resulting mixture was subjected to a reaction for 30 minutes.

The polymerization reaction liquid was heated to room temperature, and the resulting polymerization reaction liquid was concentrated and replaced with propylene glycol methyl ether acetate (PGMEA). Then, 1,000 g of a 2% by mass aqueous solution of oxalic acid was charged and the resulting mixture was stirred and then left to stand. Thereafter, the lower layer, i.e., an aqueous layer was removed. This operation was repeated three times to remove Li salts, and then 1,000 g of ultrapure water was charged, the resulting mixture was stirred, and then the lower layer, i.e., an aqueous layer was removed. This operation was repeated three times to remove oxalic acid, and then the resulting solution was concentrated. Thereafter, the mixture was added dropwise into 500 g of methanol to precipitate a polymer. The polymer collected by through vacuum filtration was washed twice with methanol, and then dried at 60° C. under reduced pressure, affording 9.9 g of a white block copolymer (A-1).

The block copolymer (A-1) obtained had an Mw of 5,400 and an Mw/Mn of 1.07. The polymer (A-1) was dissolved in PGMEA to prepare a solution containing 10% by mass of the polymer (A-1).

### [Synthesis Examples 2 to 10] (Synthesis of Polymers (A-2 to A-10))

Polymers (A-2 to A-10) shown in Table 1 below were also synthesized using the corresponding end treatment agents in the same manner as in Synthesis Example 1.

### [Synthesis Example 11] (Synthesis of Polymer (A-11))

A flask equipped with a cooling tube and a stirrer was charged with 50 g of propylene glycol methyl ether acetate, 15.8 g of M-1, 5.4 g of M-2, 0.08 g of 2,2′-azobis(2-methylpropionitrile), and 0.5 g of methyl 4-cyano-4-[(dodecylsulfanylthiocarbonyl)sulfanyl]pentanoate were charged and then purged with nitrogen, and the mixture was heated to 80° C. After polymerization was conducted for 5 hours, 1.1 g of M-6 as an additional monomer and 0.08 g of 2,2′-azobis(2-methylpropionitrile) were added, and the mixture was heated at 80° C. for 3 hours.

The resulting polymerization reaction liquid was added dropwise to 500 mL of methanol, and purification by precipitation was conducted to remove residual monomers, an initiator, and the like, thereby affording a polymer. The resulting polymer was dissolved in 40 g of propylene glycol methyl ether acetate and charged into a flask equipped with a cooling tube and a stirrer. Then, 0.47 g of 2,2′-azobis(2-methylpropionitrile) and 0.58 g of mercaptoundecene were added, and the mixture was heated to 90° C. and reacted for 2 hours. The resulting reaction liquid was added dropwise to 500 mL of methanol, and purification by precipitation was conducted to remove residual monomers, an initiator, and the like, thereby affording a polymer (A-11).

The polymer (A-11) obtained had an Mw of 6,540 and an Mw/Mn of 1.33. The polymer (A-11) was dissolved in PGMEA to prepare a solution containing 10% by mass of the polymer (A-11).

### [Synthesis Example 12] (Synthesis of Polymer (A-12))

Polymer (A-12) shown in Table 1 below was also synthesized using the corresponding compounds in the same manner as in Synthesis Example 11.

TABLE 1

| | | Monomer | | | | | | End | | |
|---|---|---|---|---|---|---|---|---|---|---|
| Synthesis | | | Ratio | | Ratio | Additional | Ratio | treatment | Molecular | |
| Example | Polymer | Monomer 1 | [mol %] | Monomer 2 | [mol %] | monomer | [mol %] | agent | weight | Mw/Mn |
| Synthesis | A-1 | M-3 | 100 | — | — | — | — | E-1 | 5400 | 1.07 |
| Example 1 | | | | | | | | | | |
| Synthesis | A-2 | M-3 | 100 | — | — | — | — | E-1 | 10500 | 1.12 |
| Example 2 | | | | | | | | | | |
| Synthesis | A-3 | M-3 | 100 | — | — | — | — | E-2 | 5270 | 1.09 |
| Example 3 | | | | | | | | | | |
| Synthesis | A-4 | M-3 | 100 | — | — | — | — | E-3 | 5310 | 1.08 |
| Example 4 | | | | | | | | | | |
| Synthesis | A-5 | M-3 | 100 | — | — | — | — | E-4 | 4990 | 1.10 |
| Example 5 | | | | | | | | | | |
| Synthesis | A-6 | M-4 | 100 | — | — | — | — | E-4 | 4230 | 1.09 |
| Example 6 | | | | | | | | | | |
| Synthesis | A-7 | M-5 | 100 | — | — | — | — | E-4 | 4630 | 1.11 |
| Example 7 | | | | | | | | | | |
| Synthesis | A-8 | M-1 | 100 | — | — | — | — | E-1 | 5560 | 1.07 |
| Example 8 | | | | | | | | | | |
| Synthesis | A-9 | M-2 | 100 | — | — | — | — | E-1 | 7250 | 1.08 |
| Example 9 | | | | | | | | | | |
| Synthesis | A-10 | M-2 | 100 | — | — | — | — | E-2 | 6502 | 1.07 |
| Example 10 | | | | | | | | | | |
| Synthesis | A-11 | M-1 | 70 | M-2 | 25 | M-6 | 5 | — | 6540 | 1.33 |
| Example 11 | | | | | | | | | | |
| Synthesis | A-12 | M-1 | 65 | M-2 | 30 | M-7 | 5 | — | 5640 | 1.31 |
| Example 12 | | | | | | | | | | |

### <Synthesis of Block Copolymer>

### [Synthesis Example 13] (Synthesis of Block Copolymer (P-1))

A 500 mL flask reaction vessel was dried under reduced pressure, and then 200 g of tetrahydrofuran which had been subjected to dehydration treatment by distillation was charged into the vessel under a nitrogen atmosphere, and cooled to −78° C. Thereafter, 0.27 g of a 1 N sec-butyllithium (sec-BuLi) solution in cyclohexane was charged, and then 10.7 g (0.103 mol) of styrene which had been subjected to dehydration treatment was added dropwise over 30 minutes. After completion of the dropwise addition, the mixture was aged for 30 minutes. Thereafter, 10.3 g (0.103 mol) of methyl methacrylate which had been subjected to dehydration treatment by distillation was further added dropwise over 30 minutes, and the mixture was reacted for 120 minutes. Thereafter, 1 mL of methanol was charged as an end treatment agent, and the resulting mixture was reacted.

The polymerization reaction liquid was heated to room temperature, and the resulting polymerization reaction liquid was concentrated and replaced with propylene glycol methyl ether acetate (PGMEA). Then, 1,000 g of a 2% by mass aqueous solution of oxalic acid was charged and the resulting mixture was stirred and then left to stand. Thereafter, the lower layer, i.e., an aqueous layer was removed. This operation was repeated three times to remove Li salts, and then 1,000 g of ultrapure water was charged, the resulting mixture was stirred, and then the lower layer, i.e., an aqueous layer was removed. This operation was repeated three times to remove oxalic acid, and then the resulting solution was concentrated. Thereafter, the mixture was added dropwise into 500 g of methanol to precipitate a polymer. The polymer collected by through vacuum filtration was washed twice with methanol, and then dried at 60° C. under reduced pressure, affording 20.5 g of a white block copolymer (P-1).

The block copolymer (P-1) obtained had an Mw of 41,000 and an Mw/Mn of 1.13. As a result of the ¹³C-NMR analysis, it was found that the proportion of the styrene unit in the block copolymer (P-1) and the proportion of the methyl methacrylate unit were 50.1 mol % and 49.9 mol %, respectively. It is noted that the block copolymer (P-1) was a diblock copolymer.

### <Preparation of Composition for Underlayer Film Formation>

The components used for the preparation of compositions for underlayer film formation are described below.

### [Component [A]]

A-1 to A-12: Solutions containing 10% by mass of the polymers (A-1) to (A-12) synthesized in Synthesis Examples 1 to 12 above.

### [Solvent [B]]

B-1: propylene glycol monomethyl ether acetate

### [Example 1] (Preparation of Composition for Underlayer Film Formation (S-1))

100 parts by mass of a solution containing 10% by mass of (A-1) as compound [A] and 397 parts by mass of (B-1) as solvent [B] were mixed and dissolved, affording a mixed solution. The resulting mixed solution was filtered through a membrane filter having a pore size of 0.1 μm to prepare a composition for underlayer film formation (S-1).

### Examples 2 to 6 and Comparative Examples 1 to 5

Compositions for underlayer film formation (S-2) to (S-7) and (CS-1) to (CS-5) were prepared in the same manner as in Example 1 except that the components with the types and the blending amounts shown in Table 1 below were used.

TABLE 2

| | | Composition for underlayer film formation | | | | | | | | | | | |
|---|---|---|---|---|---|---|---|---|---|---|---|---|---|
| | | S-1 | S-2 | S-3 | S-4 | S-5 | S-6 | S-7 | CS-1 | CS-2 | CS-3 | CS-4 | CS-5 |
| Solution | A-1 | 100 | | | | | | | | | | | |
| containing | A-2 | | 100 | | | | | | | | | | |
| compound [A] | A-3 | | | 100 | | | | | | | | | |
| (parts by mass) | A-4 | | | | 100 | | | | | | | | |
| | A-5 | | | | | 100 | | | | | | | |
| | A-6 | | | | | | 100 | | | | | | |
| | A-7 | | | | | | | 100 | | | | | |
| | A-8 | | | | | | | | 100 | | | | |
| | A-9 | | | | | | | | | 100 | | | |
| | A-10 | | | | | | | | | | 100 | | |
| | A-11 | | | | | | | | | | | 100 | |
| | A-12 | | | | | | | | | | | | 100 |
| Compound [B] | B-1 | 397 | 397 | 397 | 397 | 397 | 397 | 397 | 397 | 397 | 397 | 397 | 397 |
| (parts by mass) | | | | | | | | | | | | | |

### <Preparation of Composition for Pattern Formation>

The block copolymer (P-1) obtained was dissolved in PGMEA to prepare a 1% by mass solution. This solution was filtered through a membrane filter having a pore size of 200 nm to prepare a composition for pattern formation (J-1).

### <Measurement of Surface Free Energy>

Using each of the compositions for underlayer film formation prepared above, a coating film having a film thickness of 50 nm was formed on a Si substrate, and baked at 170 to 200° C. for 180 seconds. The measurement of the contact angle of a surface of a substrate subjected to underlayer film formation treatment was conducted under an environment specified by a room temperature of 23° C., a humidity of 45%, and normal pressure using a contact angle meter (“DMo-701” manufactured by Kyowa Interface Science Co., Ltd.). Surface free energy was calculated from a value of a water contact angle quickly measured after forming a 2.5 μL water droplet on a substrate and a value of a contact angle measured after forming a 2.0 μL droplet of diiodomethane on the same substrate.

### <Evaluation of Application Defect Performance>

Using each of the compositions for underlayer film formation prepared above, a coating film having a film thickness of 50 nm was formed on a surface of a 12 inch silicon wafer, and baked at 100° C. for 60 seconds. Each of the resulting substrates with a directed self-assembled film formed thereon was subjected to defect inspection using a defect inspector (“KLA 2810” manufactured by KLA-Tencor Corporation), and the number of defects was measured. The defect inhibiting property was evaluated as “o (good)” when the number of residual defects was 150 or less per wafer, and was evaluated as “x (poor)” when the number of residual defects was more than 150.

### [Favorableness of Fingerprint Pattern]

### <Underlayer Film Formation Treatment>

Using each of the compositions for underlayer film formation prepared above, a coating film having a film thickness of 50 nm was formed on a surface of a silicon wafer substrate, and baking was conducted at 200° C. for 180 seconds. Subsequently, in order to remove the compound [A] not interacting with the substrate, the baked resultant was washed with propylene glycol methyl ether acetate (PGMEA), and then the substrate was dried at room temperature for 30 seconds, and thus underlayer film formation treatment of the substrate was conducted.

### <Formation of Fingerprint Pattern and Favorableness of Pattern>

Onto a silicon wafer substrate having an underlayer film formed on a surface thereof, a composition for pattern formation (J-1) was applied such that a resulting directed self-assembled film would have a film thickness of 30 nm, and thus a coating film was formed. Then, the coating film was heated at 250° C. for 10 minutes to undergo phase separation, so that a microdomain structure was formed. The formed pattern was observed with a scanning electron microscope (“S-4800” manufactured by Hitachi, Ltd.) to evaluate the favorableness of the fingerprint (FP) pattern.

The favorableness of a fingerprint pattern was evaluated as “O (good)” when clear phase separation was confirmed and there was no defect, and was evaluated as “x (poor)” when phase separation was incomplete or there was a defect.

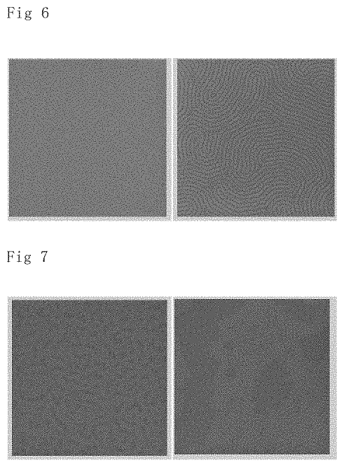

The evaluation results are shown in Table 3 and FIGS. 6 and 7.

TABLE 3

| | Composition | Surface free | Application | Favor- |
|---|---|---|---|---|
| | for underlayer | energy | defect | ableness of |
| | film formation | [mJ/m2] | performance | FP pattern |
| Example 1 | S-1 | 45.8 | ◯ | ◯ |
| Example 2 | S-2 | 45.4 | ◯ | ◯ |
| Example 3 | S-3 | 45.9 | ◯ | ◯ |
| Example 4 | S-4 | 45.3 | ◯ | ◯ |
| Example 5 | S-5 | 45.2 | ◯ | ◯ |
| Example 6 | S-6 | 46.0 | ◯ | ◯ |
| Example 7 | S-7 | 46.3 | ◯ | ◯ |
| Comparative | CR-1 | 47.8 | ◯ | X |
| Example 1 | | | | |
| Comparative | CR-2 | 45.2 | ◯ | X |
| Example 2 | | | | |
| Comparative | CR-3 | 45.3 | ◯ | X |
| Example 3 | | | | |
| Comparative | CR-4 | 43.8 | X | ◯ |
| Example 4 | | | | |
| Comparative | CR-5 | 44.3 | X | ◯ |
| Example 5 | | | | |

As shown in Table 3, as a result of the evaluations, in each of the patterns produced in Examples 1 to 7 using the compositions for underlayer film formation of the present disclosure, it was demonstrated that the application defect performance was superior, the fingerprint pattern was good (FIG. 6), and the phase separation structure by directed self-assembly could be well generated. On the other hand, in each of the patterns produced in Comparative Examples 1 to 5, the application defect performance or the fingerprint pattern (FIG. 7) was poor.

Using the directed self-assembly lithography process using the composition for underlayer film formation of the present disclosure, a phase separation structure by directed self-assembly can be favorably formed. Therefore, they can be suitably used in a lithography process in the manufacture of various electronic devices such as semiconductor devices and liquid crystal devices, which are required to be further miniaturized.

Obviously, numerous modifications and variations of the present invention are possible in light of the above teachings. It is therefore to be understood that within the scope of the appended claims, the invention may be practiced otherwise than as specifically described herein.

What is claimed is:

1. A composition comprising:
a polymer (1) having a partial structure represented by formula (1); and
a solvent, 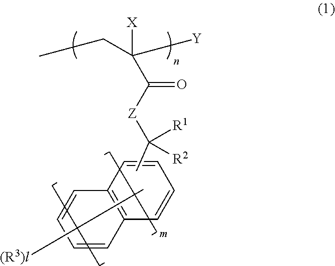
wherein in the formula (1),
X is a hydrogen atom, a halogen atom, a hydroxyl group, an alkyl group having 1 to 5 carbon atoms, a hydroxyalkyl group having 1 to 5 carbon atoms, or a halogenated alkyl group having 1 to 5 carbon atoms;
n is an integer of 10 to 500;
m is an integer of 0 to 3;
l is an integer satisfying l=2 m+5;
Y is a monovalent organic group having 1 to 12 carbon atoms and containing a hetero atom or a monovalent inorganic acid group;
Z is a linking group represented by —O—, —S—, or —NR—, where R is an organic group having 1 to 20 carbon atoms;
R¹ and R² are each independently a hydrogen atom, a halogen atom, or an organic group having 1 to 20 carbon atoms, or R¹ and R² taken together represent a divalent cyclic group having 3 to 8 ring atoms together with the carbon atom to which R¹ and R² are bonded; and
R³ is a hydrogen atom, a halogen atom or an organic group having 1 to 20 carbon atoms, provided that when there is a plurality of R³s, each R³ is the same or different.

2. The composition according to claim 1, wherein one end group Y of the polymer (1) is a cyano group, an amino group, a hydroxyl group, a phosphoric acid group, a phosphate ester group, a sulfonic acid group, a sulfonate ester group, a sulfinate ester group, or a group having a halogen atom.

3. The composition according to claim 1, wherein
the polymer (1) is any one of polymers (2) to (4) having partial structures represented by formulas (2) to (4), respectively, 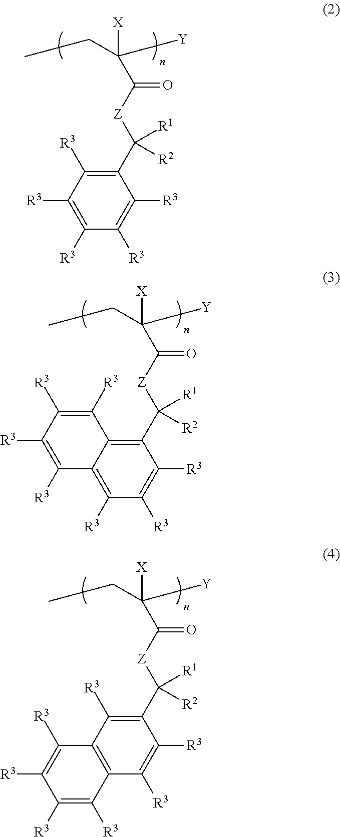
wherein in the formulas (2) to (4), X, Y, Z, R¹, R², and R³ are each as defined in the formula (1).

4. The composition according to claim 1, wherein the polymer (1) is obtained by anionic polymerization.

5. The composition according to claim 1, wherein the polymer (1) has a molecular weight distribution (Mn/Mw) of 1.10 or less.

6. The composition according to claim 1, wherein one end group Y of the polymer (1) is an amino group, a hydroxyl group, a phosphoric acid group, a phosphate ester group, a sulfonic acid group, a sulfonate ester group, or a sulfinate ester group.

7. The composition according to claim 1, wherein the composition is suitable for underlayer film formation onto a silicon-containing substrate in a directed self-assembly lithography process.

8. The composition according to claim 1, wherein the composition is suitable for underlayer film formation onto a metal-containing film in a directed self-assembly lithography process.

9. An underlayer film of a directed self-assembled film, formed from the composition according to claim 1.

10. A directed self-assembly lithography process comprising:
applying the composition according to claim 1 on one surface of a substrate to form an underlayer film;
applying a composition for directed self-assembled film formation to a surface of the underlayer film, the surface being opposite to a substrate side, to form a directed self-assembled film;
phase-separating the directed self-assembled film to form a plurality of phases in the directed self-assembled film; and
removing at least part of the plurality of phases of the directed self-assembled film to form a pattern.

11. The directed self-assembly lithography process according to claim 10, further comprising etching the substrate using the pattern as a mask.

12. The directed self-assembly lithography process according to claim 10, further comprising forming a pre-pattern on one surface of the underlayer film or the substrate, the one surface being on a side to which the composition for directed self-assembled film formation is applied,
wherein the pre-pattern has a recess, and the composition for directed self-assembled film formation is put into the recess of the pre-pattern when applying the composition for directed self-assembled film formation.

13. The directed self-assembly lithography process according to claim 10, wherein a line-and-space pattern or a hole pattern is formed by the directed self-assembly lithography process.

14. The directed self-assembly lithography process according to claim 10, wherein the substrate is a silicon-containing substrate or a substrate having a metal-containing film formed on a surface thereof.
